(19) United States
(12) Patent Application Publication
(10) Pub. No.: US 2012/0028423 A1
(43) Pub. Date: Feb. 2, 2012

(54) METHOD FOR FABRICATING SEMICONDUCTOR DEVICE

(75) Inventors: Takeshi Araya, Osaka (JP); Tsutomu Komatani, Kanagawa (JP)

(73) Assignees: SUMITOMO ELECTRIC DEVICE INNOVATIONS, INC., Yokohama-shi (JP); SUMITOMO ELECTRIC INDUSTRIES, LTD., Osaka (JP)

(21) Appl. No.: 13/192,731

(22) Filed: Jul. 28, 2011

(30) Foreign Application Priority Data
Jul. 30, 2010 (JP) 2010-171681

(51) Int. Cl. H01L 21/337

(52) U.S. Cl. 438/191; 257/E21.449

(57) ABSTRACT

A method for fabricating a semiconductor device includes: forming a channel layer; forming an electron supply layer on the channel layer; forming a cap layer made of gallium nitride on the electron supply layer; and performing an oxygen plasma treatment to an upper surface of the cap layer at a power density of 0.0125˜0.15 W/cm².

### CROSS-REFERENCE TO RELATED APPLICATION

This application is based upon and claims the benefit of priority of the prior Japanese Patent Application No. 2010-171681 filed on Jul. 30, 2010, the entire contents of which are incorporated herein by reference.

### BACKGROUND

(i) Technical Field

A certain aspect of the embodiments discussed herein is related to a method for fabricating a semiconductor device. Another aspect of the embodiments is related to a method for fabricating a semiconductor device including a nitride semiconductor layer.

(ii) Related Art

A semiconductor devices using a nitride semiconductor such as an FET (Field Effect Transistor) may be used as a power device operating at high frequencies and outputting high power. Japanese Patent Application Publication No. 2009-200306 discloses an art in which SiN (silicon nitride) films having different refractive indexes are formed to remove impurities from a surface of a semiconductor layer.

In the art, a carrier such as an electron is captured by an impurity such as oxygen on the surface of the semiconductor layer and current collapse may be caused. The current collapse reduces the output of the semiconductor device.

### SUMMARY

According to an aspect of the present invention, there is provided a method for fabricating a semiconductor device including: forming a channel layer; forming an electron supply layer on the channel layer; forming a cap layer made of gallium nitride on the electron supply layer; and performing an oxygen plasma treatment to an upper surface of the cap layer at a power density of 0.0125˜0.15 W/cm2.

### BRIEF DESCRIPTION OF THE DRAWINGS

FIGS. 1A through 1C are cross-sectional views that illustrate a method for fabricating a semiconductor device in accordance with a first embodiment;

FIGS. 2A through 2C are cross-sectional views that illustrate sequential steps that follow the process illustrated in FIGS. 1A through 1C; and

FIGS. 3A and 3B are graphs of experimental results.

### DETAILED DESCRIPTION

Embodiments of the invention are now described with reference to the accompanying drawings.

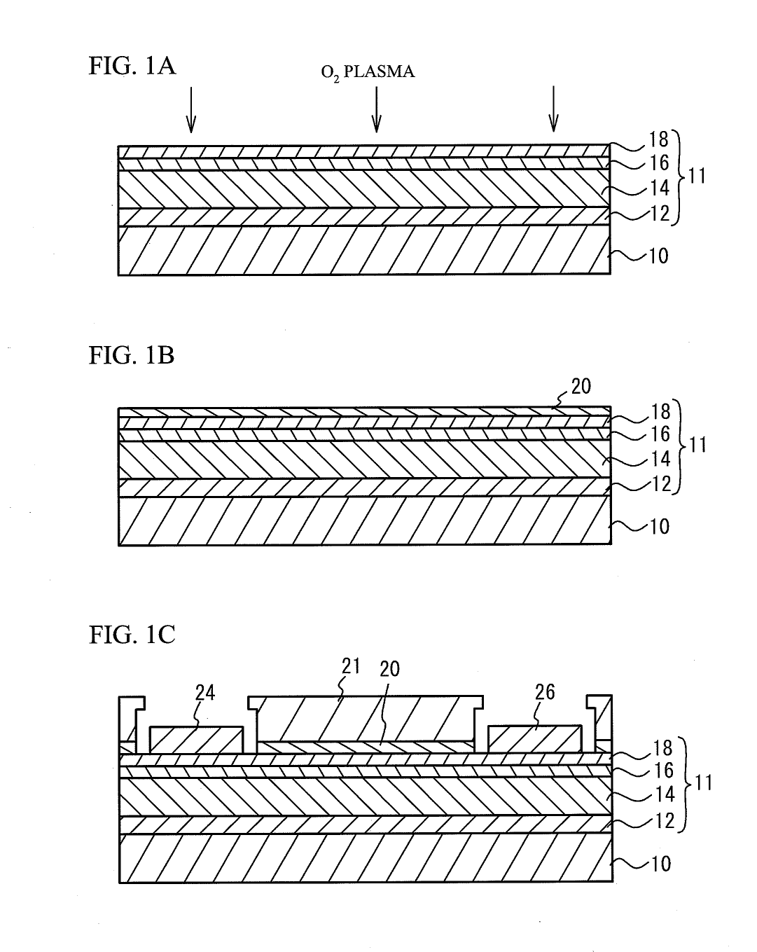

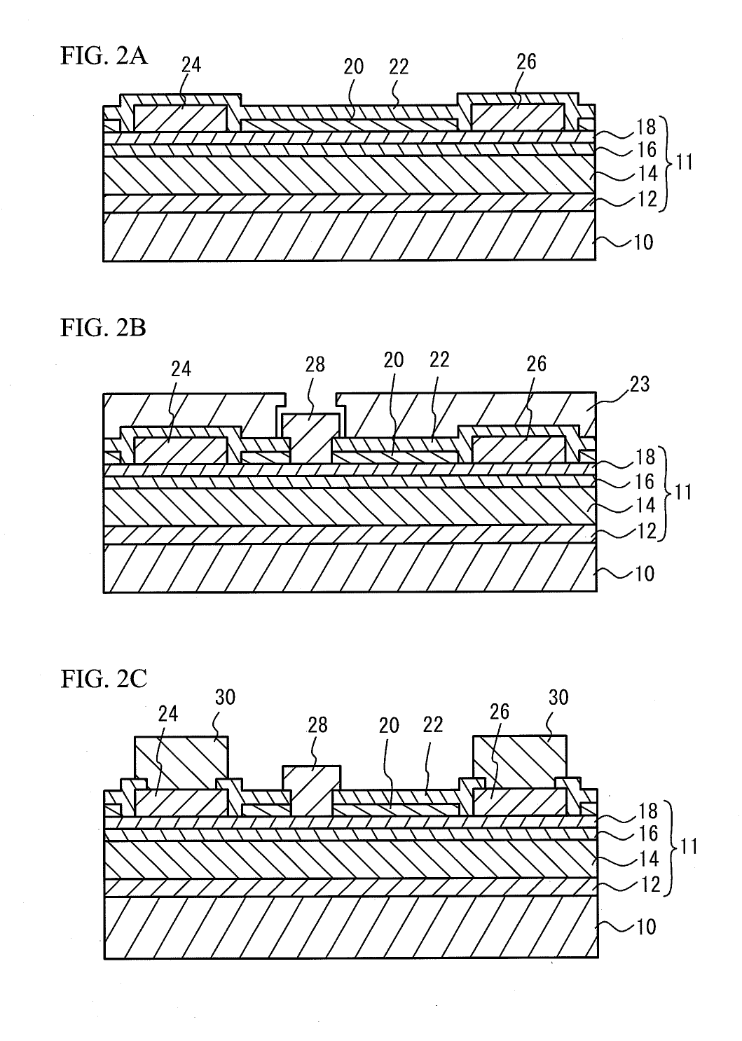

The current collapse is caused so that carriers such as electrons are captured by impurities on the surface of a semiconductor layer, particularly, oxygen. According to a first embodiment, gettering of oxygen is introduced by a plasma treatment. FIGS. 1A through 1C and 2A through 2C are cross-sectional views that illustrate a method for fabricating a semiconductor device in accordance with the first embodiment.

Referring to FIG. 1A, a semiconductor substrate is epitaxially formed on a substrate 10 by MOCVD (Metal Organic Chemical Vapor Deposition). The semiconductor substrate is composed of a barrier layer 12, a channel layer 14, an electron supply layer 16 and a cap layer 18, which layers are sequentially stacked in this order on the substrate 10. A nitride semiconductor layer 11 is formed by the barrier layer 12, the channel layer 14, the electron supply layer 16 and the cap layer 18. The cap layer 18 is formed on the electron supply layer 16. The substrate 10 may be made of, for example, SiC (silicon carbide), Si (silicon) or sapphire. The barrier layer 12 is made of AlN (aluminum nitride) and is 300 nm thick, for example. The channel layer 14 is made of i-GaN (gallium nitride) and is 1000 nm thick, for example. The electron supply layer 16 is made of AlGaN (aluminum gallium nitride) and is 20 nm thick, for example. The cap layer 18 is made of n-GaN and is 5 nm thick, for example.

The upper surface of the cap layer 18 is treated by an oxygen plasma treatment by which oxygen on the surface of the cap layer 18 is gettered. The oxygen plasma treatment may be carried out under the following condition.

Apparatus: Opposed barrel asher

Electrode area of asher: 4000 cm²

Power of plasma: 50˜600 W (which corresponds to a power density of 0.0125˜0.15 W/cm²)

Temperature in chamber: 25˜50° C.

Processing time: 2˜10 minutes

Gases supplied to the chamber and ratio: oxygen:nitrogen=1:0˜10

As illustrated in FIG. 1B, after the oxygen plasma treatment, a SiN layer 20 is formed on the upper surface of the cap layer 18 by, for example, plasma-assisted CVD (Chemical Vapor Deposition). For example, the SiN layer 20 has a thickness of 20 nm and a refractive index of 2.05˜2.45. The condition for growing the SiN layer 20 is as follows.

Apparatus: Parallel plate type plasma CVD

Temperature in chamber: 250˜350° C.

Pressure: 0.8˜1.0 Torr (106.64˜133.3 Pa)

Power: 25˜75 W

Source and flow rate: SiH₄ (monosilane):NH₃ (ammonia):nitrogen:helium=3˜6:0˜2:200˜600:500˜900 sccm (5.07×10⁻³˜10.14×10⁻³:0˜3.38×10⁻³:338×10⁻³˜1014×10⁻³:845×10⁻³˜1520.9×10⁻³ Pa·m³/sec).

Referring to FIG. 1C, a resist 21 is formed on the SiN layer 20, which is then patterned. A source electrode 24 and a drain electrode 26 are formed on exposed surface portions of the cap layer 18 defined by patterning. The source electrode 24 and the drain electrode 26 are ohmic electrodes composed of Ti/Al or Ta/Al in which Ti contacts the cap layer 18. The step of forming the source electrode 24 and the drain electrode 26 includes annealing at a temperature of, for example, 400˜800° C. in a nitrogen atmosphere for the purpose of obtaining good ohmic contacts. That is, the step of forming the SiN layer 20 is followed by annealing.

Referring to FIG. 2A, a SiN layer 22 having a thickness of, for example, 40 nm is formed on the cap layer 18, the SiN layer 20, the source electrode 24 and the drain electrode 26 by plasma-assisted CVD. The refractive index of the SiN layer 22 is, for example, 2.05˜2.45. The condition for growing the SiN layer 22 is the same as that for the SiN layer 20.

Referring to FIG. 2B, a resist 23 is formed on the SiN layer 22, and the SiN layers 20 and 22 are then patterned. A gate electrode 28 is formed on an exposed surface portion of the cap layer 18 defined by patterning. The gate electrode 28 may be composed of stacked metals such as Ni/Al where Ni contacts the cap layer 18.

Referring to FIG. 2C, interconnections 30 are formed on the source electrode 24 and the drain electrode 26. The interconnections 30 may be formed of a metal such as gold. The semiconductor device of the first embodiment may be fabricated as described above. The semiconductor device thus fabricated is a HEMT (High Electron Mobility Transistor) composed of the channel layer 14, the electron supply layer 16 and the cap layer 18 of GaN.

A description is now given of an experiment conducted by the inventors. In the experiment, an XPS (X-ray Photoelectron Spectroscopy) analysis and the operating characteristics of the semiconductor device were measured.

The XPS analysis is now described. This measures the strength of Si—O coupling (silicon-oxygen coupling strength) in the SiN layers 20 and 22 in order to evaluate the effects of gettering by the oxygen plasma treatment. Oxygen on the surface of the cap layer 18 is absorbed in the SiN layers 20 and 22 by annealing. This means that, as the Si—O coupling strength in the SiN layers 20 and 22 after annealing becomes larger, more oxygen remains on the surface of the cap layer 18. In other words, as the Si—O coupling strength becomes smaller, gettering of oxygen on the surface of the cap layer 18 by the oxygen plasma treatment is carried out more strongly.

Samples used in the XPS analysis are described below. Sample A was not treated by the oxygen plasma treatment, and samples B and C were treated by the oxygen plasma treatment. Each of the samples A, B and C was annealed when the ohmic electrodes were formed. The conditions for the oxygen plasma treatment and the annealing are as follows.

Power: 400 W (power density 0.1 W/cm²)

Oxygen plasma treatment time for sample B: 1 minute

Oxygen plasma treatment time for sample C: 3 minutes

Gases supplied to the chamber and ratio: oxygen:nitrogen=1:4

Temperature of annealing: 550° C.

Processing time of annealing: 5 minutes

In each sample, the Si—O coupling strength before annealing was 0.11.

The results of the XPS analysis are described. Table 1 shows the results of the XPS analysis. The Si—O coupling strength of the sample A was 0.11 before annealing and was 0.2 after annealing. That is , the Si—O coupling strength of sample A rose by 0.09. The Si coupling strength of the sample B was 0.11 before annealing and was 0.16 after annealing. That is, the Si—O coupling strength of sample B rose by 0.05. The Si—O coupling strength of sample C was 0.11 before annealing and was 0.14 after annealing. That is, the Si—O coupling strength of sample C rose by 0.03.

TABLE 1

| | Si—O coupling |
|---|---|
| | strength |
| Sample A | 0.2 |
| Sample B | 0.16 |
| Sample C | 0.14 |

The samples B and C had a small rise of the Si—O coupling strength after annealing, as compared with the sample A. The sample C having a comparatively long oxygen plasma treatment time had a small rise of the Si—O coupling strength after annealing, as compared with the sample B. The small rise of the Si—O coupling strength means that only a little oxygen remains on the cap layer 18. It can been from that above that the oxygen plasma treatment getters oxygen of the cap layer 18.

Next, the measurement of the characteristics is described. First, samples are described. Samples used in the measurement included sample D that was not treated by the oxygen plasma treatment and sample E that was treated by the oxygen plasma treatment. The condition for the oxygen plasma treatment used for producing the sample E is as follows. It is to be noted that parameters having the same values as those previously described are not described here.

Power: 400 W (power density 0.1 W/cm²)

Processing time: 3 minutes

Gases supplied to the chamber and ratio: oxygen:nitrogen=1:4.

The characteristics of the semiconductor devices measured were DC characteristics of the samples D and E measured by a three-terminal method in which pulse signals of Vds and Vgs were input in a case where the drain-source voltage Vds is 0 V and the gate-source voltage Vgs is 0 V and another case where Vds=50 V and Vgs=−3 V (pinch-off state). The gate voltage of the signal was changed every 0.4 V between −2 V and +2V. The pulse width of the signal was 4 μsec, and the duty ratio was 1%. The width of the gate electrode 28 (gate width) was 1 mm, and the length thereof (gate length) was 0.9 μm. The width direction corresponds to the direction vertical to the drawing sheet of FIG. 2C and the length direction corresponds to the lateral direction in FIG. 2C.

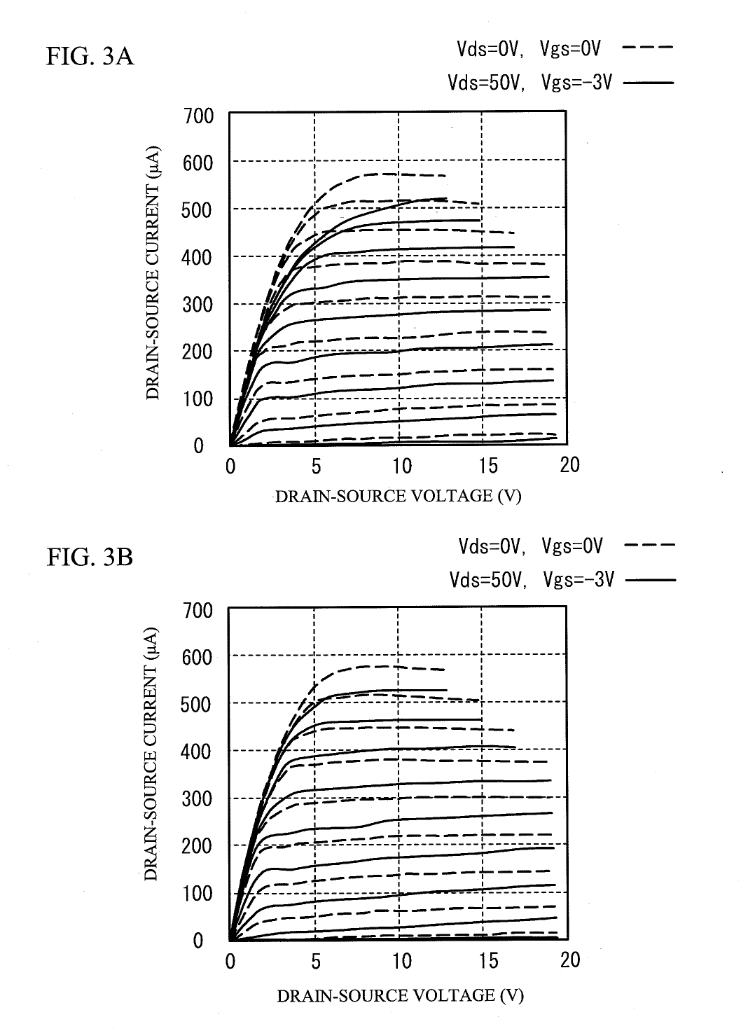

FIGS. 3A and 3B are graphs that describe experimental results. FIG. 3A is measurement results of sample D that was not treated by the oxygen plasma treatment, and FIG. 3B is measurement results of sample E that was treated by the oxygen plasma treatment. The horizontal axis of each graph denotes the drain-source voltage, and the vertical axis denotes the drain-source current. Broken lines are measurement results of the case where Vds=0 V and Vgs=0 V, and solid lines are measurement results of the case where Vds=50 V and Vgs=−3 V. As the difference between the broken line and the solid line is larger, the current collapse occurs more strongly.

The difference between the broken line and the solid line of the sample E is smaller than that of the sample D. This shows that the oxygen plasma treatment suppresses the current collapse.

According to the first embodiment, oxygen on the cap layer 18 is gettered by the oxygen plasma treatment of the cap layer 18. Since oxygen that captures electrons of the channel layer 14 is gettered, the occurrence of the current collapse may be suppressed.

The power density of the oxygen plasma treatment may have a value that enables oxygen gettering sufficiently. However, if power is too high, the nitride semiconductor layer 11 may be damaged considerably. Thus, the power density is preferably 0.0125˜0.15 W/cm². The power density may be equal to or higher than 0.0125 W/cm² and lower than 0.15 W/cm². Further, the power density may be 0.02˜0.13 W/cm². The oxygen plasma treatment may be configured to supply only oxygen gas or both of oxygen gas and nitrogen gas. The nitrogen gas indicates high impedance to high or RF frequencies. Thus, a supply of nitrogen gas makes it possible to control the plasma impedance. That is, a supply of nitrogen gas makes it easy to control oxygen plasma and adjust the gettering energy.

Also, oxygen gettering may be introduced by annealing after the SiN layer 20 is formed besides the oxygen plasma treatment. According to the first embodiment, oxygen gettering may be done effectively and the occurrence of current collapse may be suppressed by the oxygen plasma treatment and the annealing after the SiN layer 20 is formed. Another insulation layer may be substituted for the SiN layer 20 and may be annealed. In order to suppress the occurrence of current collapse, it is preferable to use the SiN layer 20.

The step of annealing uses a barrel chamber in which the semiconductor substrate is annealed at a temperature of at least 300° C. for about 30 minutes. If the temperature is low, gettering of oxygen may be insufficient. In contrast, if the temperature is high, the crystal of the nitride semiconductor layer 11 may be damaged. Thus, the annealing temperature is preferably 400˜800° C. and is more preferably 450˜700° C.

In the first embodiment, the annealing step is included in the step of forming the ohmic electrodes (source electrode 24 and the drain electrode 26). The annealing step may not be included in the step of forming the ohmic electrodes but may be a separate step.

The nitride semiconductor layer 11 may be made of a nitride semiconductor other than AlN, GaN, AlGaN. The nitride semiconductor is a semiconductor that includes nitrogen, and may be InN (indium nitride), InGaN (indium gallium nitride), InAlN (indium aluminum nitride), AlInGaN (aluminum indium gallium nitride) and so on.

The present invention is not limited to the specifically disclosed embodiments but various embodiments and variations may be made without departing the scope of the present invention.

What is claimed is:

1. A method for fabricating a semiconductor device comprising:
forming a channel layer;
forming an electron supply layer on the channel layer;
forming a cap layer made of gallium nitride on the electron supply layer; and
performing an oxygen plasma treatment to an upper surface of the cap layer at a power density of 0.0125˜0.15 W/cm².

2. The method according to claim 1, further comprising:
forming an insulation layer on the upper surface of the cap layer after the oxygen plasma treatment is performed; and
annealing the insulation layer.

3. The method according to claim 2, wherein the insulation layer comprises silicon nitride.

4. The method according to claim 1, wherein the channel layer is comprised of gallium nitride, and the electron supply layer is comprised of aluminum gallium nitride.

5. The method according to claim 1, wherein oxygen plasma treatment is performed in a plasma asher.

6. The method according to claim 1, wherein the oxygen plasma treatment is performed for 2 to 10 minutes.

7. The method according to claim 1, wherein the oxygen plasma treatment is performed at 25 to 50° C.

8. The method according to claim 1, wherein the oxygen plasma treatment is performed for 2 to 10 minutes at a temperature of 25 to 50° C.

9. The method according to claim 1, wherein the performing of the oxygen plasma treatment includes supplying an oxygen gas and a nitrogen gas.

10. The method according to claim 2, wherein the performing of the oxygen plasma treatment includes supplying an oxygen gas and a nitrogen gas.

11. The method according to claim 3, wherein the performing of the oxygen plasma treatment includes supplying an oxygen gas and a nitrogen gas.

12. The method according to claim 1, wherein the semiconductor device has a gate electrode, a source electrode and a drain electrode.
